(19) United States
(12) Patent Application Publication
(10) Pub. No.: US 2004/0109285 A1
(43) Pub. Date: Jun. 10, 2004

(54) Personal digital assistant

(76) Inventor: Huang-Lin Lee, Kuei Shan Hsiang (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(21) Appl. No.: 10/385,339

(22) Filed: Mar. 10, 2003

(30) Foreign Application Priority Data
Dec. 10, 2002 (TW) 91135706

(51) Int. Cl. H05K 5/00

(52) U.S. Cl. 361/683

(57) ABSTRACT

A personal digital assistant (PDA). The personal digital assistant (PDA) comprises a main body and a PDA stylus. The PDA stylus has a first joining portion at the end thereof. The main body has a directional control portion disposed thereon with a spherical surface rotatable around a spherical center. The directional control portion has a second joining portion at the center of the spherical surface. The PDA stylus becomes a joystick by joining the first joining portion to the second joining portion.

### BACKGROUND OF THE INVENTION

1. Field of the Invention

This invention relates to a personal digital assistant (PDA). In particular, it relates to a PDA using a PDA stylus as a joystick.

2. Description of the Related Art

With the variety of portable electronic products, PDA applications have become more and more popular. Since the PDA is small and easy to carry, it is convenient for use when traveling.

Referring to FIG. 1, the conventional PDA 1 has a display panel 12 disposed on the front bezel. The display panel 12 displays text and images such that users operate the PDA 1 according to the display information. As shown in FIG. 1, a directional control pad 11 is disposed in the lower central part of the front bezel with up, down, left and right buttons such that users control the cursor on the display panel 12. Particularly when playing games, the directional control pad 11 is often used. Moreover, the conventional PDA 1 is usually provided with a PDA stylus (not shown) for users to click icons and write on the display panel 12. In general, the PDA stylus can be stored inside or apart from the PDA 1 as an accessory.

As mentioned above, the conventional PDA 1 uses the directional control pad 11 controlling the cursor on the display panel 12. With the variety of software and games applied to the PDAs, however, the joystick is needed to substitute for the conventional directional control pad 11. The joystick is often connected to the PDA since it is popular and easier to use than the conventional directional control pad 11 especially when playing games. However, additional joystick device needs more space and makes the PDA complex. Therefore, it becomes important to integrate the joystick into the PDA such that the PDA is more compact and convenient to users especially when playing games.

### SUMMARY OF THE INVENTION

An object of the invention is to provide a personal digital assistant (PDA) using a PDA stylus as a joystick.

The personal digital assistant (PDA) comprises a main body and a PDA stylus. The PDA stylus has a first joining portion at the end. The main body has a directional control portion disposed thereon with a spherical surface rotatable around the spherical center. The directional control portion has a second joining portion at the center of the spherical surface. The PDA stylus becomes a joystick by joining the first joining portion to the second joining portion.

The present invention provides a personal digital assistant (PDA) needing no additional joystick device such that users can easily use the PDA stylus as a joystick, especially when playing games. Therefore, the PDA stylus has both the functions of the normal PDA stylus and the joystick. Thus, the personal digital assistant (PDA) of the present invention is not only convenient to users but also saves more space at a lower cost.

### BRIEF DESCRIPTION OF THE DRAWINGS

The present invention can be more fully understood by reading the subsequent detailed description and examples with references made to the accompanying drawings, wherein:

FIG. 1 is a perspective diagram of a conventional PDA;

FIG. 2 is a perspective diagram of the PDA in accordance with the present invention;

FIG. 3a is a sectional view of the PDA stylus in accordance with the present invention with the front and back members joined;

FIG. 3b is a sectional view of the PDA stylus in accordance with the present invention with the front member detached from the back member;

FIG. 4 is a perspective diagram of the PDA using the front member of the PDA stylus as a joystick in accordance with the present invention;

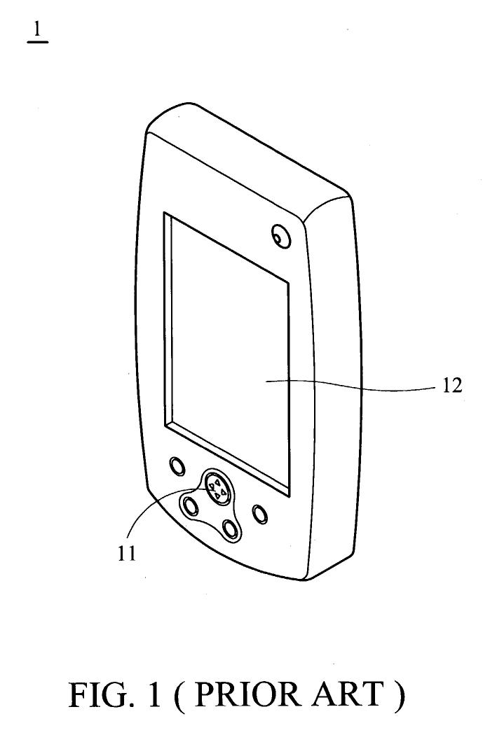

### DETAILED DESCRIPTION OF THE INVENTION

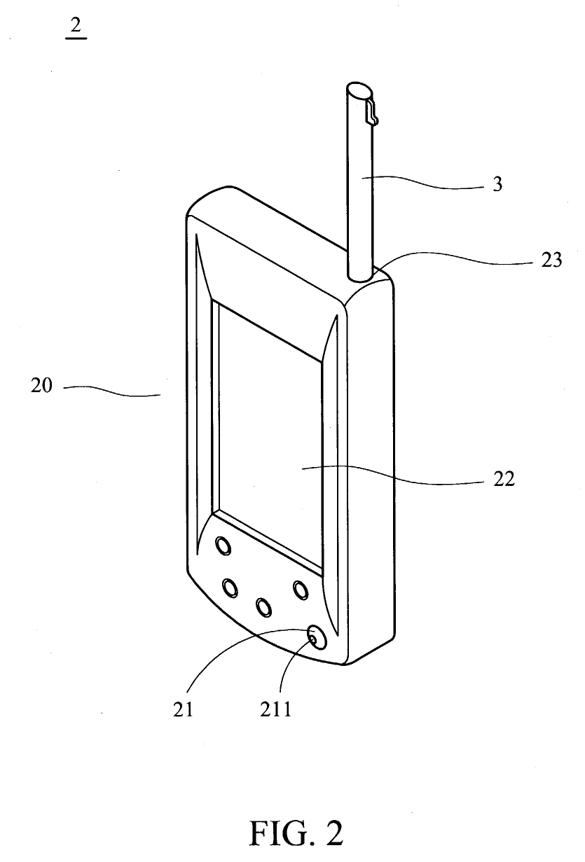

FIG. 2 is a perspective diagram of the PDA in accordance with the present invention. The PDA 2 comprises a main body 20 and a PDA stylus 3. The main body 20 has a directional control portion 21, a display panel 22 and a receiving channel 23. The display panel 22 is disposed on the front bezel of the PDA 2 and the receiving channel 23 is defined in the main body 20 such that the PDA stylus 3 can be stored therein.

As shown in FIG. 2, the directional control portion 21 is located at the bottom right corner of the front bezel with a spherical surface. Particularly, the directional control portion 21 is rotatable around the spherical center. In FIG. 2, the directional control portion 21 has a second joining portion 211 at the center of the spherical surface.

The directional control portion 21 can rotate at any angle with the spherical surface, like a trackball. When using the PDA 2, users control the cursor on the display panel 22 by rotating the directional control portion 21 with fingers contacting the spherical surface. Therefore, it is more sensitive and comfortable to users than the conventional directional control pad 11 especially when playing games.

As mentioned above, the directional control portion 21 has the second joining portion 211 at the center of the spherical surface. The second joining portion 211 in the present invention has a depression enabling joining of the PDA stylus 3 together as a joystick.

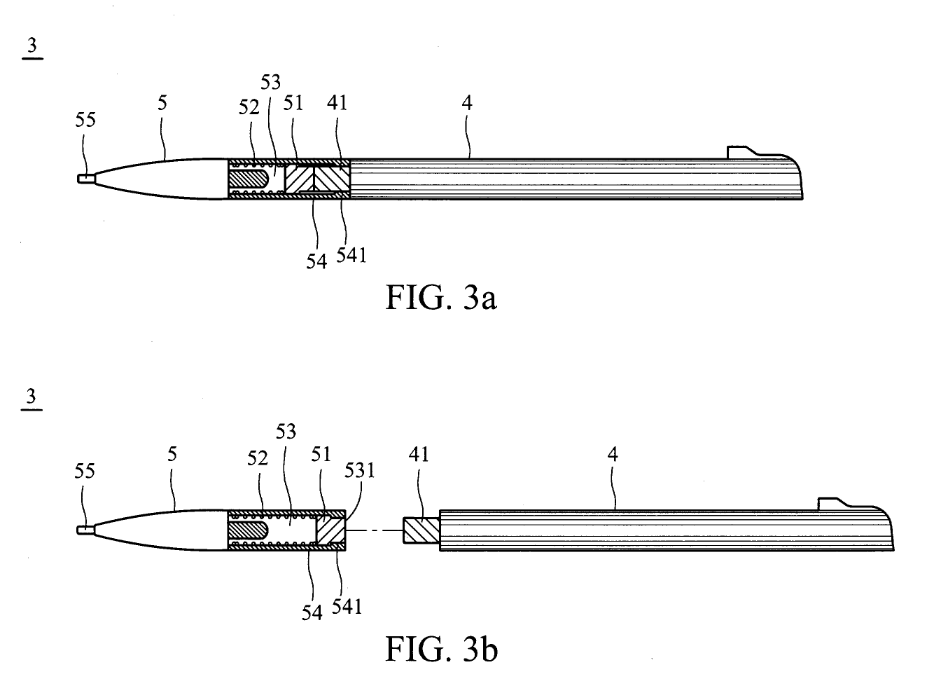

As shown in FIG. 3a and FIG. 3b, the PDA stylus 3 of the present invention includes a front member 5 and a back member 4. FIG. 3b is a sectional view of the PDA stylus 3 when the front member 5 is detached from the back member 4. As shown in FIG. 3b, a first magnet 41 is disposed at the end and projecting from the back member 4.

The front member 5 includes a chamber 53 and a housing 54, wherein the chamber 53 is defined within the housing 54. The housing 54 has an opening 531. A compression spring 52 is disposed inside the housing 54. In FIG. 3b, the compression spring 52 connects a second magnet 51 movable near the opening 531 and a rib 541 is disposed at the opening 531. When detaching the front member 5 from the back member 4, the second magnet 51 is pushed out by the compression spring 52 and stopped from falling out by the rib 541 at the opening 531 such that the opening 531 is automatically closed.

As shown in FIG. 3b, the front member 5 of the PDA stylus 3 has a first joining portion 55 at the end. The first joining portion 55 has a protrusion to join into the depression of the second joining portion 211 such that the front member 5 becomes a joystick. Moreover, the magnetic attraction between the first magnet 41 and the second magnet 51 helps to join the front member 5 and the back member 4 together.

FIG. 3a is a sectional view of the PDA stylus 3 in accordance with the present invention when the front member 5 and the back member 4 are joined together. When joining the front member 5 and the back member 4, the first magnet 41 enters the opening 531 and pushes the second magnet 51 inside the chamber 53. The first magnet 41 connects the second magnet 51 by magnetic attraction and presses the rib 541 to fit into the opening 531 such that the front member 5 and the back member 4 are tightly joined.

As mentioned above, users can selectively detach or join the front member 5 and the back member 4 of the PDA stylus 3 in different situations. When the PDA 2 is not in use, the PDA stylus 3 can be stored inside the receiving channel 23 safely. Additionally, when the front member 5 serves as a joystick, the back member 4 can still be used as a normal PDA stylus. The back member 4 and the front member 5 can be of course used together as a joystick. Thus, it is convenient for users to operate or store the PDA stylus 3 in accordance with the present invention.

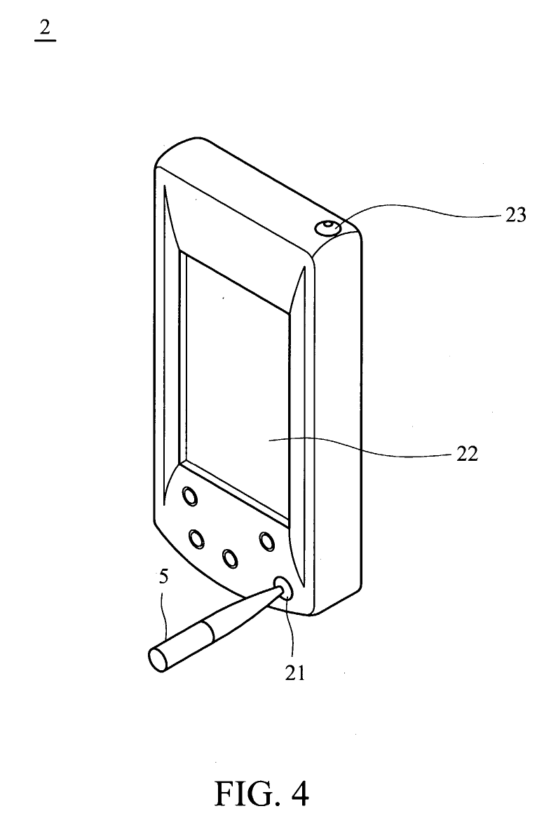

FIG. 4 is a perspective diagram of the PDA using the front member 5 of the PDA stylus 3 as a joystick in the present invention. As shown in FIG. 4, the front member 5 becomes a joystick by connecting the front member 5 of the PDA stylus 3 to the directional control portion 21. With the projecting first joining portion 55 inserted into the corresponding depression of the second joining portion 211, the front member 5 and the directional control portion 21 are joined together. Thus, users can use the front member 5 as a joystick rotating at any angle around the spherical surface of the directional control portion 21 to control the cursor on the display panel 22 especially when playing games.

When using the front member 5 as a joystick, the back member 4 can be stored in the receiving channel 23 safely to prevent loss. Additionally, users can also directly use the whole PDA stylus 3 as a joystick if the PDA stylus 3 is undetachable. Moreover, to tightly secure the front member 5 and the directional control portion 21, the first joining portion 55 can also join to the second joining portion 211 by screwing.

In summary, the personal digital assistant (PDA) in accordance with the present invention needs no additional joystick device and users can easily use the PDA stylus as a joystick, especially when playing games. Particularly, the PDA stylus has both functions of a normal PDA stylus and the joystick. Thus, the personal digital assistant (PDA) in this invention is not only convenient to users but also saves more space at a lower cost.

When the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation to encompass all such modifications and similar arrangements.

What is claimed is:

1. A personal digital assistant, comprising:
a PDA stylus, with a front member and a back member detachably connected to the front member, wherein the front member has a first joining portion;
a main body, with a directional control portion disposed thereon, the directional control portion with a spherical surface and a second joining portion, wherein the spherical surface is rotatable around a spherical center of the spherical surface, the second joining portion is disposed at a center of the spherical surface, and the front member serves as a joystick by joining the first joining portion to the second joining portion.

2. The personal digital assistant as claimed in claim 1, wherein the main body further has a receiving channel for the PDA stylus stored therein.

3. The personal digital assistant as claimed in claim 1, wherein the first joining portion has a protrusion and the second joining portion has a depression corresponding to the protrusion.

4. The personal digital assistant as claimed in claim 3, wherein the first joining portion and the second portion are joined by screwing.

5. The personal digital assistant as claimed in claim 1, wherein the back member has a first magnet disposed at an end thereof.

6. The personal digital assistant as claimed in claim 5, wherein the front member has a housing and a second magnet disposed therein.

7. The personal digital assistant as claimed in claim 6, wherein the housing has an opening and a rib disposed close to the opening.

8. The personal digital assistant as claimed in claim 6, wherein the front member has a spring disposed in the housing and connected to the second magnet.

9. The personal digital assistant as claimed in claim 8, wherein the spring is a compression spring.

10. A personal digital assistant, comprising:
a PDA stylus, having a first joining portion;
a main body, having a directional control portion disposed thereon, the directional control portion with a spherical surface and a second joining portion, wherein the spherical surface is rotatable around a spherical center, the second joining portion is disposed at a center of the spherical surface, and the front member serves as a joystick by joining the first joining portion to the second portion.

11. The personal digital assistant as claimed in claim 10, wherein the main body further has a receiving channel where the PDA stylus is stored.

12. The personal digital assistant as claimed in claim 10, wherein the first joining portion has a protrusion and the second joining portion has a depression corresponding to the protrusion.

13. The personal digital assistant as claimed in claim 12, wherein the first joining portion and the second joining portion are joined by screwing.
